(19) United States
(12) Patent Application Publication
(10) Pub. No.: US 2006/0223313 A1
(43) Pub. Date: Oct. 5, 2006

(54) Copper interconnect post for connecting a semiconductor chip to a substrate and method of fabricating the same

(75) Inventors: Seung Uk Yoon, Singapore (SG); David Witarsa, Singapore (SG); Xiao Wu Zhang, Singapore (SG); Vaidyanathan Kripesh, Singapore (SG)

Correspondence Address: Crockett & Crockett;Suite 400, 24012 Calle De La Plata, Laguna Hills, CA, 92653, US

(73) Assignee: Agency for Science, Technology and Research

(21) Appl. No.: 11/394,843

(22) Filed: Mar. 31, 2006

Related U.S. Application Data
(60) Provisional application No. 60/667,413, filed on Apr. 1, 2005.

(51) Int. Cl. H01L 21/44

(52) U.S. Cl. 438/687; 438/598

(57) ABSTRACT

A semiconductor chip comprising at least one contact area for electrically connecting the chip to a substrate, the contact area comprising a metallic contact pad covered by a seed layer and at least one copper interconnect post having a base surface directly contacting the contact area and extending from the contact area in a direction at least substantially perpendicular thereto in a tapered manner. A method for manufacturing a semiconductor chip with a copper interconnect post is also disclosed.

### CROSS-REFERENCE TO RELATED APPLICATIONS

This application claims the benefit of priority of U.S. provisional application No. 60/667,413 filed Apr. 1, 2005, the contents of each being hereby incorporated by reference it its entirety for all purposes.

### FIELD OF THE INVENTION

The present invention relates to the field of interconnections between semiconductor chips and substrates, and in particular, to a copper (Cu) interconnect post for electrically connecting a semiconductor chip to a substrate and a method of fabricating the same.

### BACKGROUND OF THE INVENTION

Flip-chip solder-bump interconnections have been used in the manufacturing of interconnections between semiconductor chips and substrates for almost forty years. Solder-bump interconnections were introduced in 1964 in an IBM System. Solder-bump interconnections were designed to extend interconnection capabilities beyond the existing wire-bonding techniques in that unlike wire-bonding (which is a process of providing electrical connection between designated portions of a semiconductor chip and external leads of a semiconductor package using very fine bonding wires), the area array solder-bump configuration allowed the entire surface of the chip (or die) to be populated with solder bumps. The solder bumps were subsequently connected to a substrate (or printed circuit board) by a Controlled Collapse Chip Connection (C4) solder reflow process in order to have the highest possible input/output (I/O) pin count to meet the ever-increasing demand for electrical functionality and reliability in integrated circuit (IC) technology.

The C4 is essentially an evaporative bump process that provides a method for producing multichip modules for the mainframe computer market and single chip packages for high-performance computing. This evaporative process deposits solder bumps on the chip or die by selectively depositing metals through a molybdenum (Mo) shadow mask. The initial process step is an argon (Ar) sputter etch step to remove the die bond pad oxidation and to ensure low electrical contact resistance. Subsequently, the evaporation of chrome (Cr), chrome-copper (Cr—Cu), copper (Cu), gold (Au) forms the under bump metallization (UBM). The UBM acts as a hermetic seal, provides an electrically conductive diffusion barrier, and establishes a good mechanical base for the solder bump. Following the UBM layer deposition, the next step is to evaporate lead (Pb), followed by tin (Sn), to form the bulk of the bump. In the unreflowed state, the bump heights are consistent across the wafer, providing a good interface for probing or burn-in. In the final step, the bump is reflowed and in doing so, homogenizes the PbSn solder and allows the tin to form an intermetallic compound with the copper of the UBM. The homogenized PbSn solder provides the necessary adhesion between the die and the bump.

However, the C4 evaporated bump technology faces difficulties with regard to its extendibility (i.e. to have a higher bump height) when bump pitch decreases below 225 μm. At a bump pitch lower than 225 μm, the method used to fix the molybdenum mask to the wafer results in non-uniform clamping at the wafer edge and bowing of the mask across the wafer. Furthermore, if the mask is not in direct physical contact with the wafer (non-uniform contact), it is possible for metals to be deposited underneath, thereby causing leakage or shorting between bumps. As bump pitch and diameters decrease, the mask must adapt accordingly and become thinner to accommodate the finer features of the shrinking bumps. As such, the thinner mask is no longer as rigid as before, and in turn this aggravates the non-uniform contact phenomenon. Another factor affecting fine pitch capability is the significant tolerance stack-up in the manual mask-to-wafer alignment procedure. This tolerance stack-up can prevent the UBM from covering a via, causing a nonhermetic seal and potential electromigration problems.

To overcome the above-mentioned problems associated with the C4 evaporated bump technology, electroplated bump or electroplating process is currently used. One of the most significant advantages of electroplated bumping technology is that it relies on photolithographic means to define the UBM and solder bump. Photolithography, in combination with a high-performance photoresist, permits extremely small structure definition and does not limit practical minimum bump pitch.

There are two types of electroplating processes namely, High Lead Electroplating Process and Eutectic Electroplating Process. High Lead Electroplating Process is a traditional plating process for solder bump formation. It is adopted from the evaporating process and uses a Cr/Cr—Cu/Cu UBM with high lead solder (97Pb/3Sn). Eutectic Electroplating Process involves bumping with a eutectic alloy (63Sn/37Pb). A eutectic alloy is a mixture of two or more elements having a melting point lower than any of its constituents. The ratio of the constituents to obtain a eutectic alloy is identified by the eutectic point on a phase diagram. The lower melting point or reflow temperature of the eutectic alloy allows the use of organic substrates, which results in lower manufacturing costs. Further benefits arising from using a eutectic alloy on organic substrates are the requirement for lower reflow temperatures, self-alignment of the photoresist mask and easier flux removal.

However, the UBM used for high lead processes is not compatible when electroplating with the eutectic alloy. The higher level of tin in the eutectic alloy consumes the copper in the UBM. This rapidly degrades the integrity of the structure. To address this issue, the deposition of an adhesion layer of titanium/tungsten (Ti/W) on the semiconductor chip is followed by a thick, solder wettable, layer of copper, which is used for the adhesion, diffusion and bonding layers. Finally, solder is deposited over the Ti/W/Cu minibump UBM by electroplating. The thick copper layer (or copper post) is necessary since as mentioned above, tin quickly consumes copper, leaving the non-wettable adhesion layer (Ti/W) in contact with the eutectic solder alloy. This thick copper layer is sometimes called a minibump or stud.

The introduction of the copper layer or copper pillar further serves to increase the standoff height between the chip and the substrate. Keeping the chip further away from the board or substrate surface has the benefit of making it less sensitive to strains caused by the differing coefficients of thermal expansion (CTE) existing between the chip and the substrate. Accordingly, the residual stress and thermal mismatch between the chip and the substrate will be reduced.

Examples of copper pillar structures are disclosed in U.S. Pat. Nos. 6,578,754 and 5,334,804. U.S. Pat. No. 6,578,754 discloses a copper pillar technology introduced to flip chip interconnection. The structure of the U.S. Pat. No. 6,578,754 comprises a copper pillar capped with a layer of solder (solder bump). This copper pillar has a high standoff of 70-80 um and prevents alpha particle which brings about soft error rate (SER) in chip circuits. However, mechanical stress occurs on the bump and this stress is introduced by the different coefficients of thermal expansion (CTE) of the substrate and the chip. The difference in CTE eventually leads to cracks in the solder bump and electrical opens. In addition, having differing adjacent metals, such as solder and metals from the UBM or bond pads, for example, also gives rise to diffusion, which advances the formation of different intermetallic compounds (IMCs) between the solder and metal interface that degrade the mechanical stability and electrical resistance of the bump. U.S. Pat. No. 5,334,804 discloses another copper interconnection structure that connects a chip to a substrate. The copper interconnection structure has a copper post mechanically mounted to the surface of the substrate. The copper post is further covered by a layer of nickel and has a solder fillet around the junction of the interface between the copper post and the surface of the substrate. Similarly, this copper post suffers from failures within the solder layer and from failures between the solder and metal interface at the chip and/or substrate side, respectively.

The interconnection structures disclosed in U.S. Pat. Nos. 6,578,754 and 5,334,804 are made using spin on photoresist templates. Using spin on photoresist templates results in high production costs and therefore renders the manufacturing process expensive in terms of the cost per I/O pin.

Therefore, there is still a need for a copper interconnect post that is mechanically stable, less susceptible to stress and economical to fabricate.

### SUMMARY OF THE INVENTION

Accordingly, the invention provides a semiconductor chip comprising at least one contact area for electrically connecting the chip to a substrate, the contact area comprising a metallic contact pad covered by a seed layer and at least one copper interconnect post having a base surface directly contacting the contact area and extending from the contact area in a direction at least substantially perpendicular thereto in a tapered manner.

In one embodiment of the invention, the copper interconnect post comprises a base fillet in direct contact with the contact area.

In another embodiment of the invention, the copper interconnect post has a top surface opposite to and at least substantially parallel with the base surface.

In a further embodiment of the invention, a layer of solder is deposited on the top surface of the copper interconnect post.

In another embodiment of the invention, a layer of one of nickel and nickel-alloy is deposited between the top surface of the copper interconnect post and the layer of solder.

The present invention also provides for a method for manufacturing a semiconductor chip with a copper interconnect post.

The method comprises:

depositing a seed layer on a surface of the semiconductor chip comprising at least one contact pad; the contact pad with the seed layer thereon defining a contact area;

applying a photosensitive dry film to a surface of the seed layer;

processing the dry film so as to expose the contact area of the semiconductor chip via a through-hole in the dry film;

filling at least a substantial portion of the through-hole with copper thereby forming a copper post, a base surface thereof being in direct contact with the contact area of the semiconductor chip; and

removing the dry film.

Another embodiment of the method comprises forming a layer of solder on a top surface of the copper post opposite to its base surface.

In another embodiment of the method, a layer of one of nickel and nickel-alloy is formed on the top surface of the copper post prior to forming the layer of solder.

In another embodiment of the method, processing the dry film comprises the steps of:
applying a mask on the dry film;
exposing the dry film to radiation; and
developing the dry film so as to expose the contact area.

In yet another further embodiment, the seed layer is etched away after removing the dry film.

The present invention further provides for a semiconductor device including a semiconductor chip comprising at least one contact area for electrically connecting the chip to a substrate, the contact area comprising a metallic contact pad covered by a seed layer; and at least one copper interconnect post having a base surface directly contacting the contact area and extending from the contact area in a direction at least substantially perpendicular thereto in a tapered manner.

The following figures illustrate various exemplary embodiments of the present invention. However, it should be noted that the present invention is not limited to the exemplary embodiments illustrated in the following figures.

### BRIEF DESCRIPTION OF THE DRAWINGS

FIG. 1 shows a cross-sectional schematic of a semiconductor chip of the invention with a copper interconnect post;

FIGS. 2A-2I show cross-sectional views illustrating steps for manufacturing a semiconductor chip with a copper interconnect post;

FIG. 3 shows a micrograph of a resultant dry film pattern after a development process;

FIG. 4 shows a cross-sectional micrograph of a semiconductor chip of the invention with a copper interconnect post having a fillet;

FIG. 5 shows a top-view micrograph of a semiconductor chip of the invention with a copper interconnect post having a fillet;

FIG. 6 shows a scanning electron microscope (SEM) micrograph of an interfacial reaction between copper and Pb-free solder (SnAgCu) as-cast of a copper interconnect post of the invention;

FIG. 7 shows a scanning electron microscope (SEM) micrograph of an interfacial reaction between copper and Pb-free solder (SnAgCu) aged at 250° C. for 30 minutes of a copper interconnect post of the invention;

FIG. 8 shows a scanning electron microscope (SEM) micrograph of an interfacial reaction between nickel and Pb-free solder (SnAgCu) as-cast of a copper interconnect post of the invention;

FIG. 9 shows a scanning electron microscope (SEM) micrograph of an interfacial reaction between nickel and Pb-free solder (SnAgCu) aged at 250° C. for 30 minutes of a copper interconnect post of the invention;

FIG. 10 shows a table tabulating diffusivity of Tin atoms in the matrices of copper and nickel at various temperatures respectively;

FIG. 11 shows a Von Mises Stress Contour in the copper interconnect post;

FIG. 12 shows solder wetting on copper and nickel layer;

FIG. 13 shows solder wetting on side of copper and nickel layer;

FIG. 14 shows a flow diagram of a method for manufacturing a semiconductor chip with a copper interconnect post.

### DETAILED DESCRIPTION OF THE INVENTION

Exemplary embodiments of a semiconductor chip or die with a copper interconnect post are described in detail below with reference to the accompanying figures. In addition, the exemplary embodiments described below can be modified in various aspects without changing the essence of the invention.

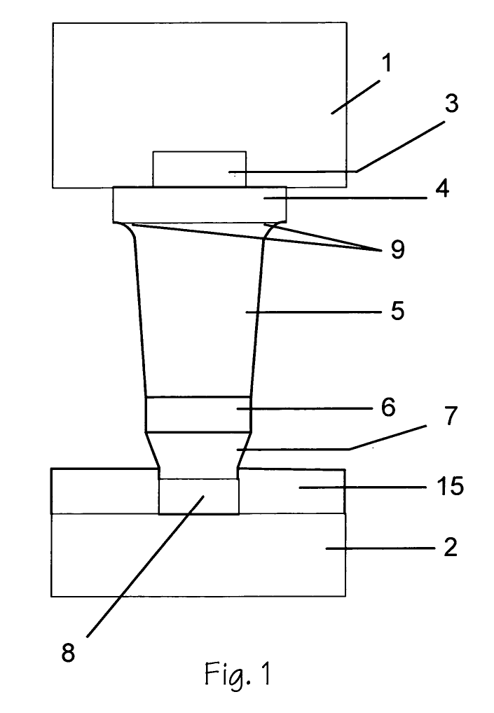

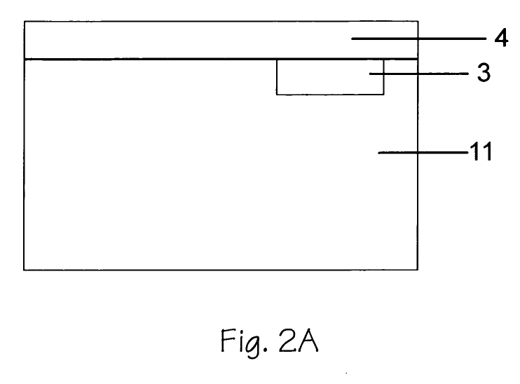

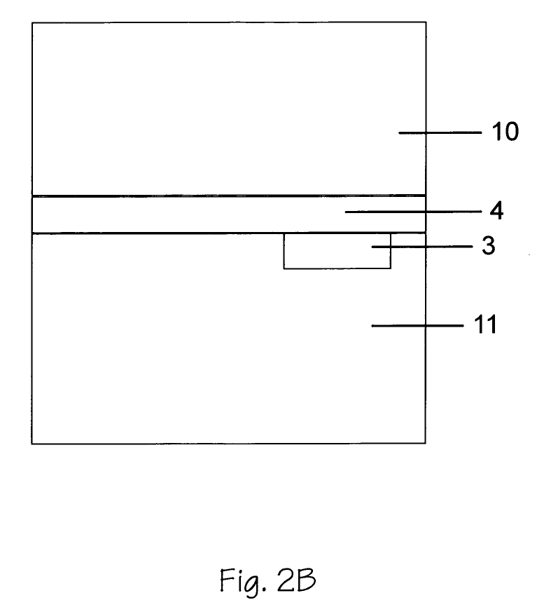

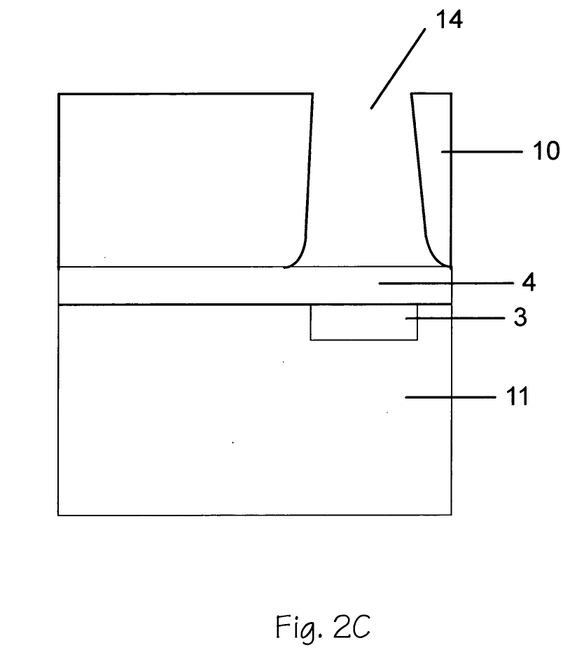

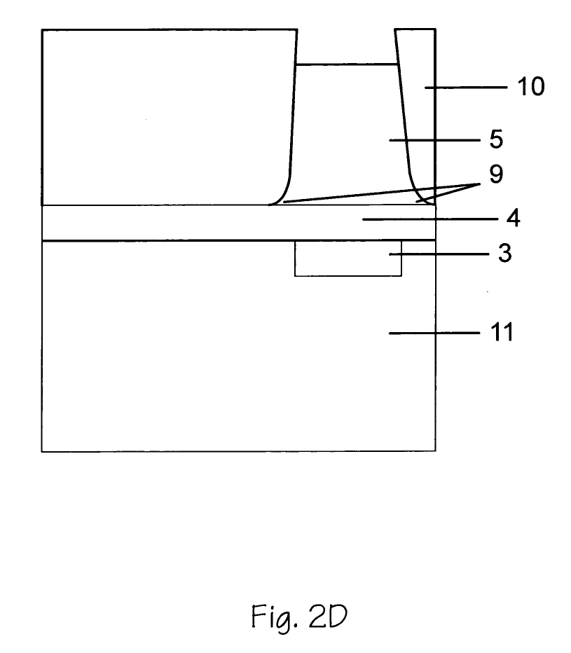

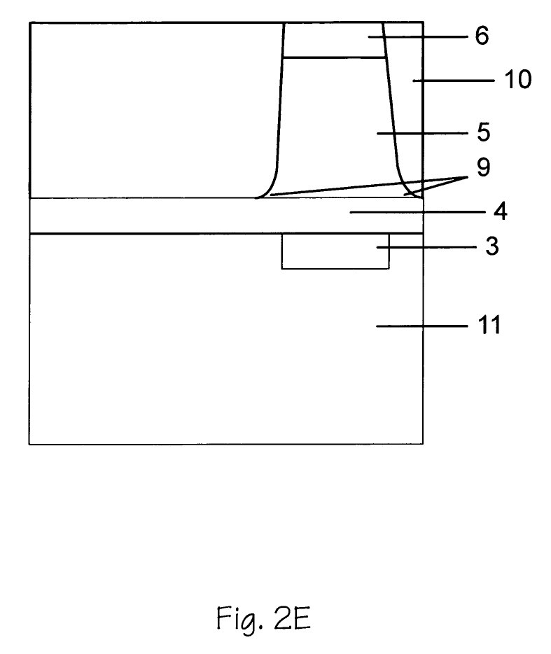

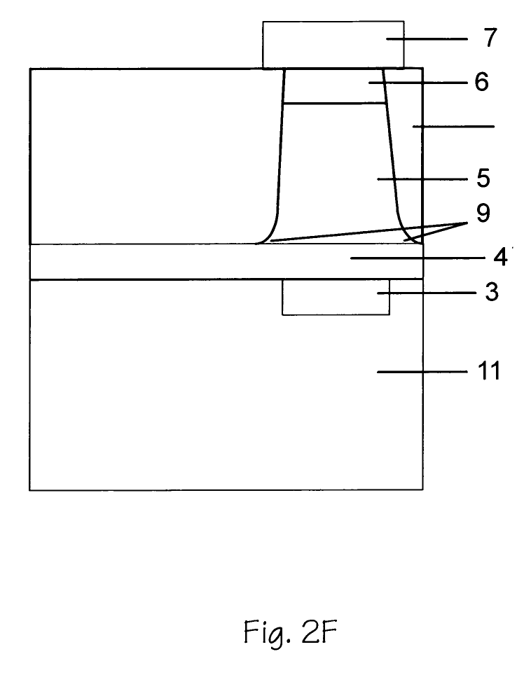

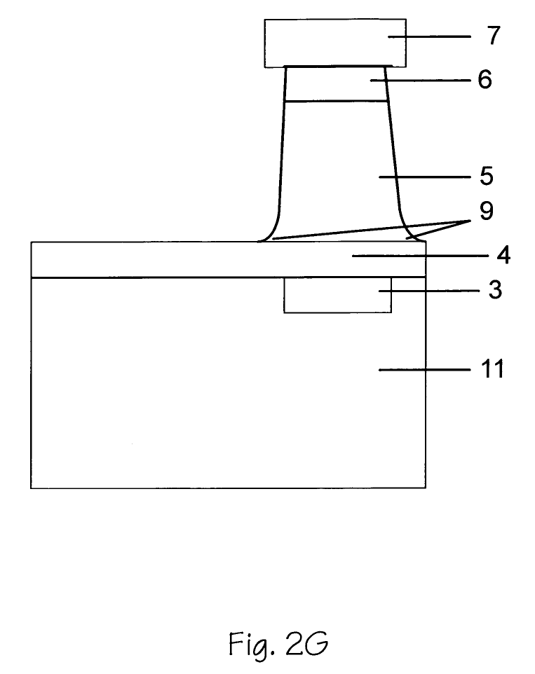

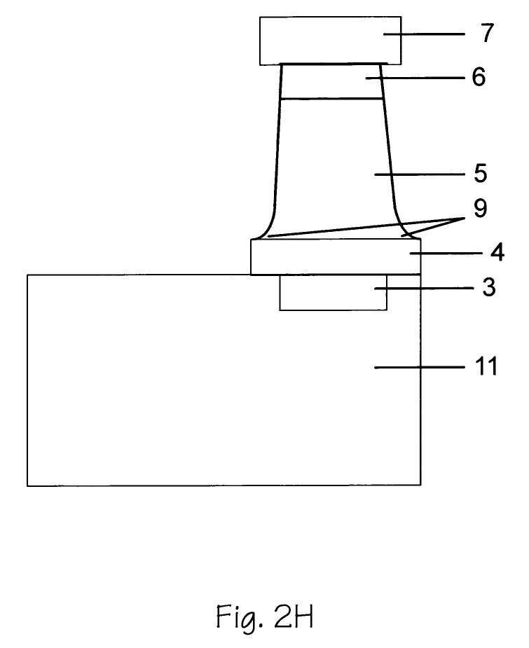

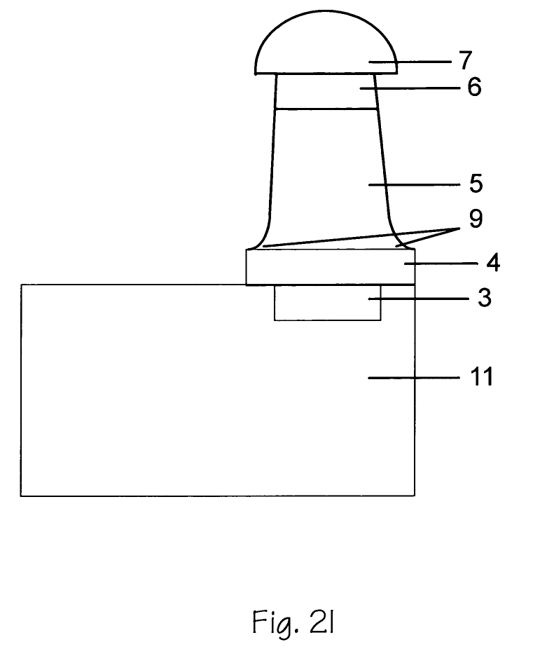

FIG. 1 shows a cross-sectional view of a semiconductor chip or die or wafer level package 1 with a copper interconnect post 5 according to the invention. The chip or die 1 is a small piece of silicon wafer 11 as shown in FIG. 2A, bounded by adjacent scribe lines in the horizontal and vertical directions. The die 1 has a contact area for electrically connecting the die 1 to a substrate pad 8 on a substrate or package 2. The contact area comprises a metallic contact pad 3 covered by a seed layer 4. The die 1 is further connected to the substrate 2 by means of a copper interconnect post 5. The copper interconnect post 5 has a base surface directly contacting the contact area and extends from the contact area in a direction substantially perpendicular to the contact area in a tapered manner. In addition, the copper interconnect post 5 has a top surface opposite to and substantially parallel with the base surface. The diameter of the base surface contacting the seed layer 4 is generally greater than the diameter of the top surface to increase the contact interface between the copper interconnect post 5 and the die 1.

To further increase the contact interface of the copper interconnect post 5 with the die 1, the copper interconnect post 5 has a fillet 9 at the base surface in direct contact with the contact area. The combination of the tapered shape with existence of a base fillet 9 in the copper interconnect post 5 gives better solder joint reliability in comparison with normal copper interconnect post or column shape.

FIG. 1 shows that a layer of nickel (Ni) 6 or Ni-alloy is arranged on the top surface of the copper interconnect post 5. The layer of nickel 6 or Ni-alloy has a thickness between about 1 μm to about 20 μm. Examples of Ni-alloy include Ni-Phosphorus (P), Ni-Vanadium (V), Ni—P—Cu, Ni-Iron (Fe)-Chromium (Cr), Ni—Cr. The layer of nickel 6 or Ni-alloy further enhances homogeneous interfacial reaction, homogeneous bulk solder morphology and microstructure. This is important to solder joint reliability and electromigration resistance performance.

As shown in FIG. 1, a layer of solder 7 is further arranged on the nickel layer 6. The layer of solder 7 generally has a thickness between about 30 μm to about 500 μm and the copper interconnect post 5 generally has a height between about 30 μm to about 500 μm. The solder 7 is then connected to the substrate 2 via a solder mask 15 defined substrate pad 8. In the case of wafer level package, the solder mask 15 is also termed as “passivation”.

FIG. 2A to 2I show cross-sectional views illustrating steps of manufacturing a semiconductor chip 1 with a copper interconnect post 5 according to the present invention.

As shown in FIG. 2A, a seed layer 4 is deposited on a surface of the silicon wafer 11 comprising at least a metallic contact pad 3. The contact pad 3 and the seed layer 4 define a contact area. The seed layer 4 is deposited by processes which include electroplating or electroless plating. Examples of the seed layer 4 include but are not limited to conductive materials or a combination of conductive materials like Titanium (Ti)/Gold (Au), Ti/Cu, Ti-alloy/Au, Ti-alloy/Cu, Ti/Ni, Ti-alloy/Ni, Cr/Au, Cr/Cu or Cr/Ni. As the metal to be electroplated in the present invention is copper, a copper or gold seed layer 4 is being deposited. The wettable metal layer such as copper or gold seed layer 4, laid down prior to copper electroplating serves as an adhesion layer during the electroplating process.

After depositing the seed layer 4 on the silicon wafer 11, a layer of photosensitive dry film 10 is applied to a surface of the seed layer 4 as shown in FIG. 2B. The layer of dry film 10 is preformed or cut to the desired shape before being hot-roll laminated onto the surface of the seed layer 4. The layer of dry film 10 is photosensitive, meaning that it is a material that experiences a change in its physical properties when exposed to a radiation source. The dry film includes any commercially available dry film. Examples include Ashai Sunfort dry film, Dupont dry film, JSR dry film, Nichgo ALPHO dry film. The average thickness of the dry film is typically between about 10 to about 100 μm or about 10 to about 200 μm. For example, if a thickness of 200 μm is required, a double lamination can be carried out.

Referring next to FIG. 2C, the dry film 10 is processed so as to expose the contact area of the silicon wafer 11 via a through-hole 14 in the dry film 10. A mask with a designated pattern is applied or aligned to the silicon wafer 11. Various designated areas of the photosensitive dry film 10 are exposed to radiation and said areas that are exposed to radiation are developed or removed to expose the contact area on the silicon wafer 11 via a through-hole 14 in the dry film 10. The exposure dose ranges between 50 to 100 mJ/cm² for a 50 μm thickness of dry film 10 and the development process lasts approximately 2 minutes at room temperature using for example a 0.1% to 5 wt % calcium carbonate (Ca₂CO₃) solution. The radiation includes ultra-violet radiation or optical radiation. Optical radiation can also be termed as light. The wavelength of the radiation ranges from 20 nm to 800 nm.

Portions of the through-hole 14 are subsequently filled with copper 5 by a process termed electroplating as shown in FIG. 2D. Electroplating is the process by which a metal in its ionic form is supplied with electrons to form a non-ionic coating on a desired substrate. The most common system involves a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

After deposition of copper 5, a layer of nickel 6 is formed or deposited on the top surface of the copper post 5 by a process which includes electroplating or electroless plating as shown in FIG. 2E. Electroless plating, also known as chemical or auto-catalytic plating, is a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the object to be plated. The most common electroless plating method is electroless nickel plating.

After deposition of the nickel layer 6, FIG. 2F shows formation or deposition of a layer of solder 7 on the top surface of the nickel layer 6 by a process which includes electroplating or solder paste printing. In solder paste printing, the silicon wafer is placed on a work holder mechanically or by vacuum, and further aligned with tooling pins or vision. Either a screen or stencil is then used to apply the solder paste. However, the layer of solder 7 can be deposited directly on the top surface of the copper post opposite to its base surface as well.

When all the respective layers, namely copper 5, nickel 6 and solder 7 have been deposited above the contact area of the silicon wafer 11, the dry film 10 is being removed or stripped from the seed layer 4 as shown in FIG. 2G. Stripping is the removal of the dry film 10 from the seed layer 4, and involves immersing the structure containing the dry film in a heated solution of sodium hydroxide (stripper solution) (or commonly known as caustic soda, lye, or sodium hydrate) and agitating the sodium hydroxide until the dry film 10 lifts off from the seed layer 4. The dry film 10 can be stripped with an alkali containing solution such as sodium hydroxide. The sodium hydroxide has a typical concentration of 1 to 10 wt %.

After removal of the dry film 10, the seed layer 4 is etched away leaving the interconnect structure as shown in FIG. 2H. Etching refers to a process by which material is removed from the wafer, i.e., either from the silicon substrate itself or from any film or layer of material on the wafer. There are two major types of etching: dry etching and wet etching.

Dry Etching is an etching process that does not utilize any liquid chemicals or etchants to remove materials from the wafer, generating only volatile byproducts in the process. Dry etching may be accomplished by any of the following: 1) through chemical reactions that consume the material, using chemically reactive gases or plasma; 2) physical removal of the material, usually by momentum transfer; or 3) a combination of both physical removal and chemical reactions.

Wet etching on the other hand is an etching process that utilizes liquid chemicals or etchants to remove materials from the wafer, usually in specific patterns defined by photoresist masks on the wafer. Materials not covered by these masks are etched away by the chemicals while those covered by the masks are left almost intact. A simple wet etching process may just consist of dissolution of the material to be removed in a liquid solvent, without changing the chemical nature of the dissolved material. In general, however, a wet etching process involves one or more chemical reactions that consume the original reactants and produce new species. A basic wet etching process may be broken down into three (3) basic steps: 1) diffusion of the etchant to the surface for removal; 2) reaction between the etchant and the material being removed; and 3) diffusion of the reaction byproducts from the reacted surface.

After etching of the seed layer 4, the solder layer 7 is then heated to reflow the solder 7 in the case of electroplated solder to achieve the resulting spherical structure as shown in FIG. 2I. Solder reflow is a high-temperature process that melts the solder paste so that it can form the final solder connection between the semiconductor wafer 11 or chip 1 and the substrate 2.

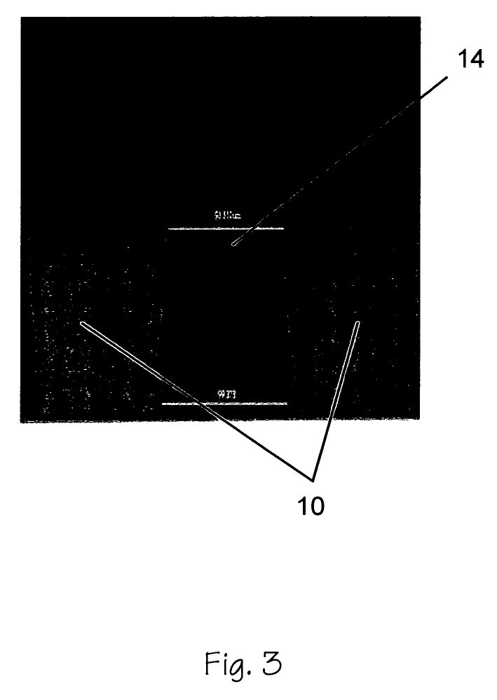

FIG. 3 shows a micrograph of the resultant dry film 10 pattern after the development process. The resultant dry film 10 has a tapered through-hole 14, exposing the contact area of the silicon wafer 11. The diameter of a base surface of the through-hole 14 contacting the silicon wafer 11 is larger than the diameter of a top surface of the through-hole 14, resulting in a tapered shape. In addition, the resultant dry film 10 has gap at the base surface of the through-hole 14 contacting the silicon wafer 11, which results in the copper interconnect post 5 having a fillet shape 9 after electroplating.

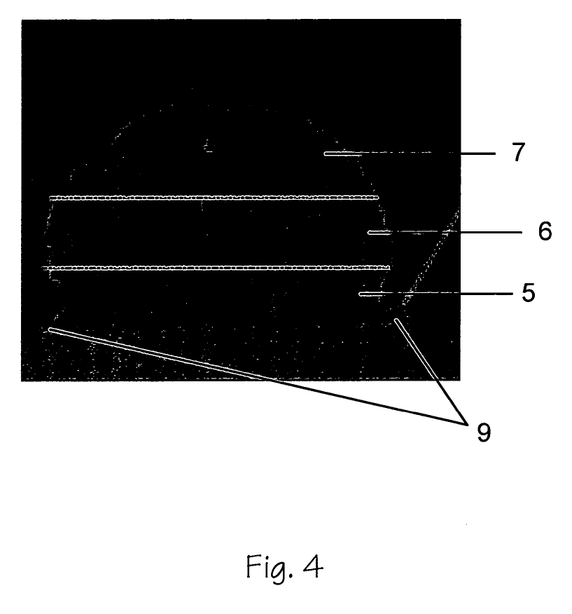

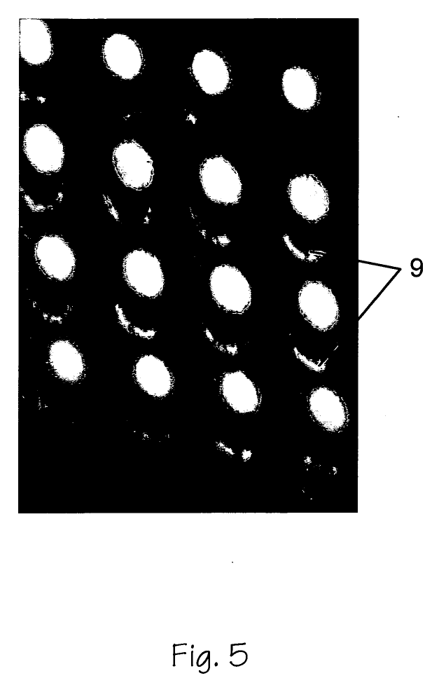

FIG. 4 shows a cross-sectional micrograph of the semiconductor chip 1 with the resultant copper interconnect post 5 having a fillet 9. FIG. 4 also shows a layer of nickel 6 deposited on the top surface of the copper interconnect post 5 and a layer of solder 7 deposited on the top surface of the nickel layer 6. The resultant interconnect structure has a tapered shape with a base fillet 9. FIG. 5 shows a top-view micrograph of the copper interconnect post 5 having a fillet 9.

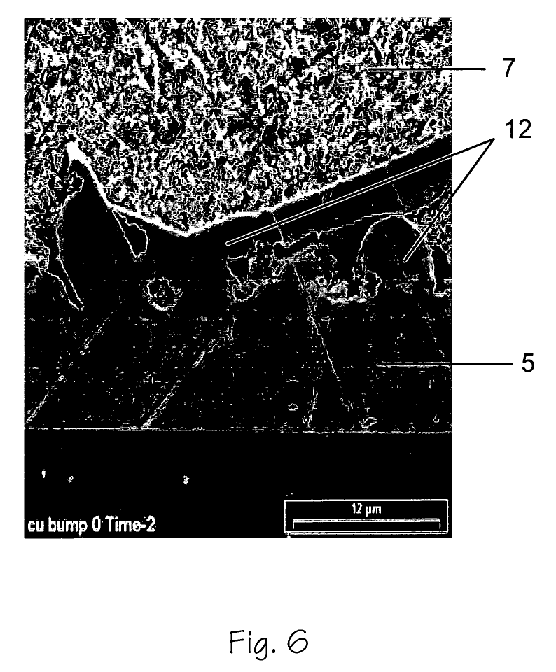

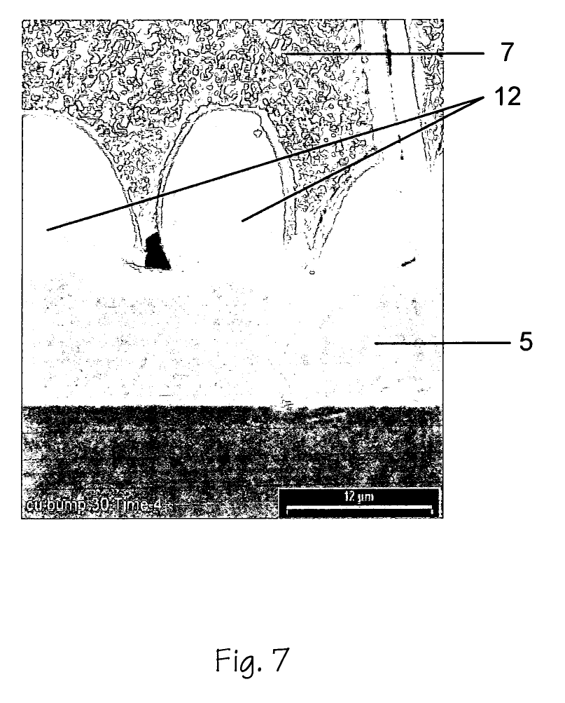

FIGS. 6 and 7 show SEM micrographs of interfacial reaction between copper 5 and lead-free solder 7 (SnAgCu) at zero-time (referred herein as “as-cast”) and aged at 250° C. for 30 minutes respectively. The interfacial reaction between copper 5 and lead-free solder 7 results in the formation of copper-tin intermetallic compounds (IMC) 12 depending on the process conditions. For example, the formation can have compositions as follows: Cu₆Sn₅ or Cu₃Sn. Cu₆Sn₅ forms just after reflow, but after aging at higher temperature, Cu₃Sn can also form from a reaction between between Cu₆Sn₅ and copper. Every tin plated copper alloy or solder in this case, experiences formation of copper-tin intermetallic compounds (Cu₆Sn₅ or Cu₃Sn) 12 at the interface of the tin and the base metal (copper in this case). An intermetallic compound consists of two or more elements, always with the same precise ratio of atoms (in this case 6:5 and 3:1). Many dissimilar metals (tin and copper) in close contact will diffuse and form intermetallic compounds. The compound initially forms at the interface of the plating and the base metal and grows until eventually all the tin is consumed. Copper-tin intermetallic compounds are hard and brittle. They are easily oxidized at the surface. The oxidized intermetallic compound can adversely affect contact resistance and solderability.

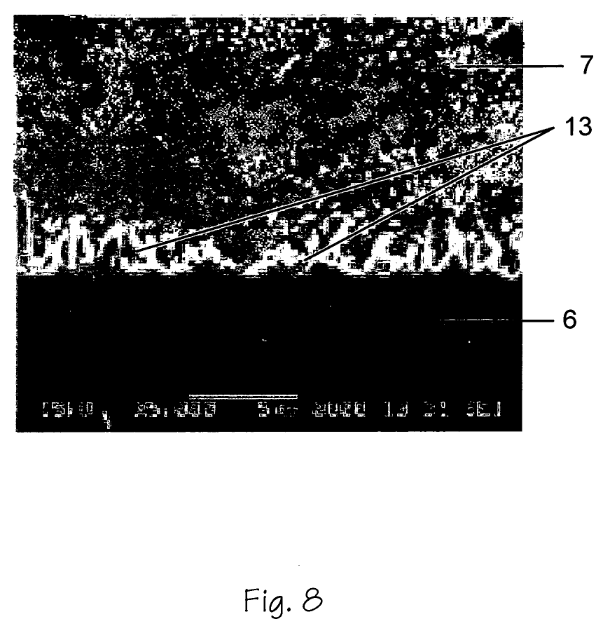

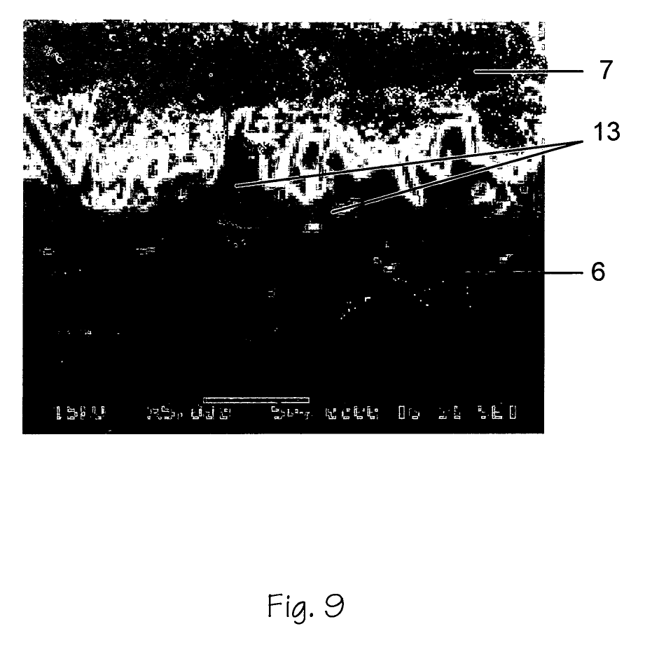

FIGS. 8 and 9 show SEM micrographs of interfacial reaction between nickel 6 and lead-free solder 7 (SnAgCu) at zero-time or as-cast and aged at 250° C. for 30 minutes respectively. The interfacial reaction between nickel 6 and lead-free solder 7 results in the formation of another nickel-tin intermetallic compounds, Ni₃Sn₄ 13

FIGS. 6 and 7 show a gradual growth of the copper-tin IMC, Cu₆Sn₅ or Cu3Sn 12 at the copper 5 and solder 7 interface at the elevated temperature of 250° C. compared to as-cast. Comparing micrographs of an embodiment depicted in FIGS. 6 and 7 to those of another embodiment depicted in FIGS. 8 and 9, the absence of a nickel layer 6 between the copper 5 and the solder layer 7 leads to thick intermetallic compounds at the copper-solder interface after extended temperature stress. Therefore the existence of a nickel layer 6 between copper 5 and solder 7 help to reduce the formation of intermetallic compounds.

The adhesion strength and interfacial properties of solder joints are generally determined by interfacial microstructure or intermetallic compounds. The evolution of interfacial microstructure in solder joints is governed by the diffusion path during processing and in service at the interface region from UBM or substrate. As intermetallic compounds are known to be very brittle, thicker intermetallic compounds are easily fractured.

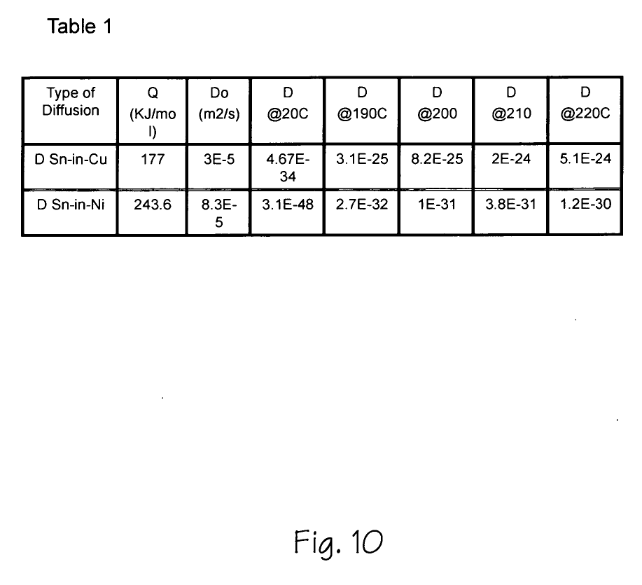

In case of flip chip dies, to enhance the performance and function of electrical devices such as microprocessors, the number of I/O contact pads on the chip surface must be increased and correspondingly, the diameter of solder bumps needs to be decreased. As a result, the current density when passing through the contact area of a solder bump increases very rapidly and the electromigration or thermo-electromigration becomes a critical reliability issue especially for high pin and power applications as in microprocessors. As shown in Table 1 (FIG. 10), the diffusivity of tin in nickel 6 is much slower than that in copper 5. Thus higher resistance of electromigration is expected when a nickel or nickel-alloy layer 6 is present between the copper post 5 and solder layer 7.

In summary, copper reacts more with tin than nickel, thus thicker intermetallic compounds are formed at the copper and lead-free solder (SnAgCu) interface. Thicker intermetallic compounds are known to result in lower adhesion strength and are easier cracked and broken. In addition, the high tin content in lead-free solders results in rapid consumption of copper from conventional copper UBM. The presence of a nickel layer between copper and lead-free solder (SnAgCu) gives better solder joint reliability due to reduction of intermetallic failures and higher electromigration resistance.

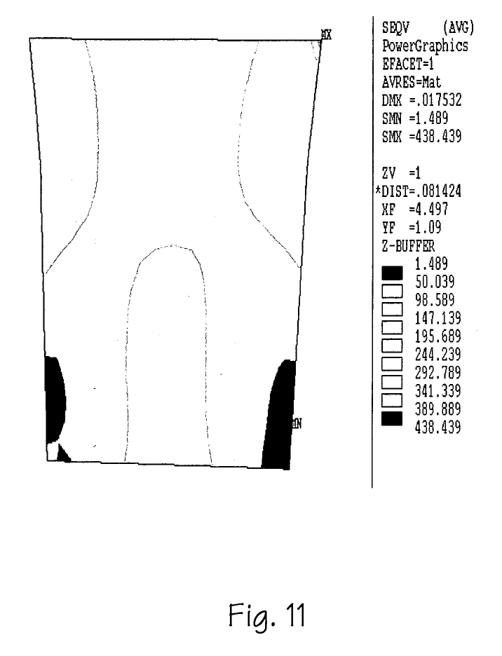

In order to investigate the mechanical reliability of the copper interconnect post 5 of the present invention, computer aided mechanical simulation had been carried out by Finite Elementary Method (FEM). After two-dimension (2-D) modelings were completed, temperature cycle loading ranging from −40° C. to 125° C. was applied and FEM works were carried out. FIG. 11 further shows a Von Mises Stress Contour of the copper interconnect post 5. The mechanical simulation shows that a higher Von Mises Stress Point exists at the chip 1 side. In one embodiment of the invention, it was found that the highest stress value for the copper interconnect post of the present invention was 438 MPa.

In terms of process and material cost of manufacturing the copper interconnect post 5, the state of the art involve using liquid type photoresist materials to make the plating mask, while preformed solid-type dry film 10 material is used in the present invention. The advantages of preformed dry film 10 photoresist used in the present invention over normal liquid type photoresist are for example: (a) No need for a track system for Photo Resist (PR) coating and developing process (b) Cheaper development and stripping chemicals (c) Lower maintenance costs (d) Faster productivity (Units Per Hour (UPH))—no need for coating and baking (normal process time about 2-3 min.) (e) More cost-effective for higher copper post (f) Better flatness and coating uniformity.

In addition, a cost estimate of liquid photoresist versus dry film photoresist material is reflected in the Table 2 below. Table 2 shows that there is at least 10 times lower material cost when using the preformed photosensitive dry film over the liquid photoresist. The table only reflects the material cost but there shall be more savings when process flow and equipment used are taken into consideration.

TABLE 2

| | | | unit | | |
|---|---|---|---|---|---|
| | | | amount | | |
| | | | per 8″ | Available | Unit PR |
| | Cost (USD) | amount | wafer | Wafer No. | cost |
| Prior Art | 990 | 900 ml | 10 ml | 90 | 11 |
| Ex)Thick PR | | | | | |
| (JSR-151N) | | | | | |
| Preformed PR | 410 | 300 m | 0.5 m | 600 | 0.68 |
| Dry film | | | | | |

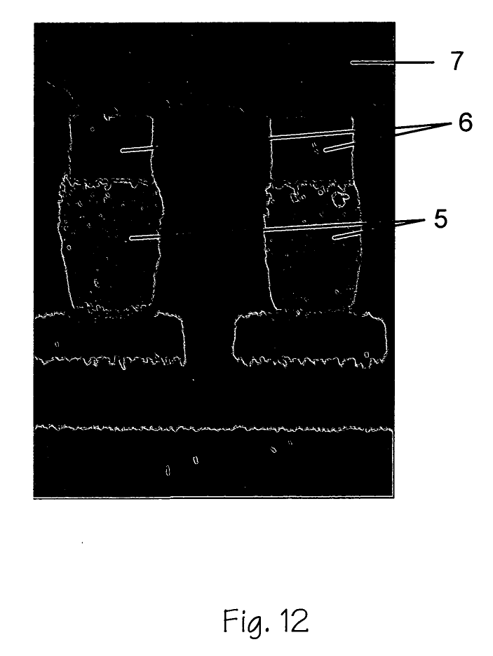

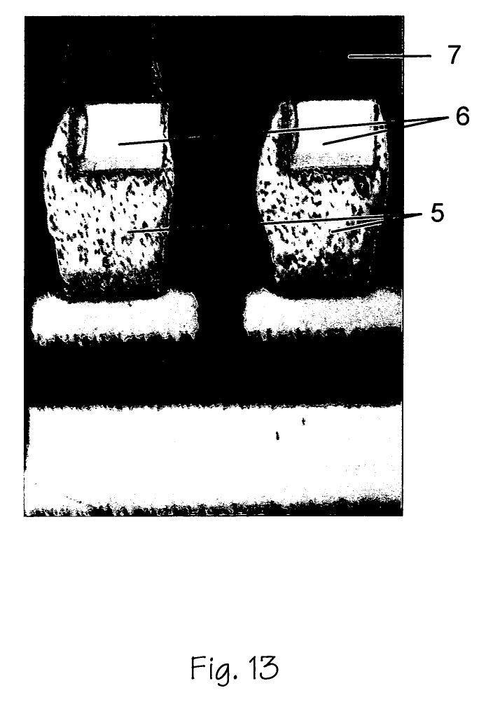

Solderability of a surface is defined by its solder wetting characteristics. Solder wetting pertains to the formation of a relatively uniform, smooth, and unbroken film of solder that exhibits excellent adherence on the soldered surface. Non-wetting, on the other hand, is the condition wherein the solder coating has contacted the surface but did not adhere completely to it, causing the surface or a part thereof to be exposed. FIG. 12 shows solder wetting on copper 5 and nickel layer 6 while FIG. 13 shows solder wetting on side of copper 5 and nickel layer 6 as a result of varying the process parameters including flux dispensation on substrate or chip side, attachment force and flux amount. Varying each of these process parameters thereby results in a different interconnection shape. In applications, where flip chips are attached onto the substrate for further second level interconnection between substrate and board, the initial first level interconnection (between flip chip and substrate) shape is very critical for solder joint reliability and further processes such as underfill. Keeping the solder volume constant, higher solder joint will result in better solder reliability. It is also beneficial to keep the solder at the bottom of the copper post wet as this will result in better solder joint reliability.

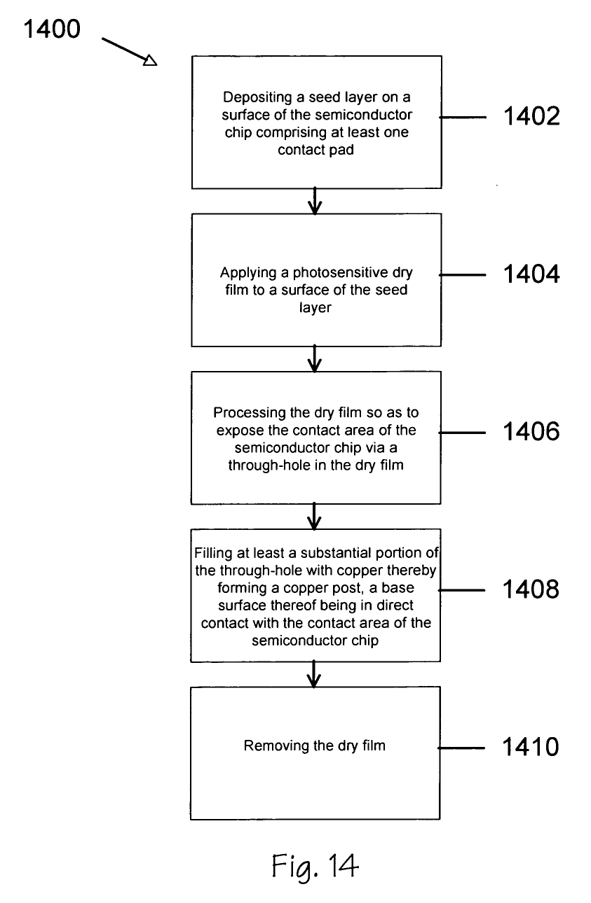

FIG. 14 shows a flow diagram of a method 1400 for manufacturing a semiconductor chip 1 with a copper interconnect post 5. The method 1400 begins at 1402 with deposition of a seed layer 4 on a surface of the semiconductor chip 1 comprising at least one contact pad 3 and the contact pad 3 with the seed layer 4 thereon defining a contact area. Next, in 1404 a photosensitive dry film 10 is applied to a surface of the seed layer 4. At 1406, the dry film 10 is processed so as to expose the contact area of the semiconductor chip 1 via a through-hole 14 in the dry film 10. At 1408 at least a substantial portion of the through-hole 14 is filled with copper 5 thereby forming a copper post 5 and a base surface thereof being in direct contact with the contact area of the semiconductor chip 1. At 1410 the dry film 10 is removed.

The aforementioned description of the various embodiments has been presented for purposes of illustration and description. It is not intended to be exhaustive or to limit the invention to the precise form disclosed, and obviously many modifications and variations are possible in light of the disclosed teaching. It is intended that the scope of the invention be defined by the claims appended hereto.

What is claimed is:

1. A semiconductor chip comprising:
at least one contact area for electrically connecting the chip to a substrate;
the contact area comprising a metallic contact pad covered by a seed layer; and
at least one copper interconnect post having a base surface directly contacting the contact area and extending from the contact area in a direction at least substantially perpendicular thereto in a tapered manner.

2. The semiconductor chip of claim 1, wherein the copper interconnect post comprises a base fillet in direct contact with the contact area.

3. The semiconductor chip of claim 1, wherein the copper interconnect post has a height between about 30 to about 500 μm.

4. The semiconductor chip of claim 1, wherein the copper interconnect post has a top surface opposite to and at least substantially parallel with the base surface.

5. The semiconductor chip of claim 4, wherein a layer of solder is deposited on the top surface of the copper interconnect post.

6. The semiconductor chip of claim 5, wherein the layer of solder has a thickness between about 30 to about 500 μm.

7. The semiconductor chip of claim 5, wherein a layer of one of nickel and nickel-alloy is deposited between the top surface of the copper interconnect post and the layer of solder.

8. The semiconductor chip of claim 7, wherein the layer of nickel has a thickness between about 1 to about 20 μm.

9. A method for manufacturing a semiconductor chip with a copper interconnect post comprising:
depositing a seed layer on a surface of the semiconductor chip comprising at least one contact pad;
the contact pad with the seed layer thereon defining a contact area;
applying a photosensitive dry film to a surface of the seed layer;
processing the dry film so as to expose the contact area of the semiconductor chip via a through-hole in the dry film;
filling at least a substantial portion of the through-hole with copper thereby forming a copper post, a base surface thereof being in direct contact with the contact area of the semiconductor chip; and
removing the dry film.

10. The method of claim 9, wherein filling the through-hole with copper is carried out by electroplating.

11. The method of claim 9, further comprising forming a layer of solder on a top surface of the copper post opposite to its base surface.

12. The method of claim 11, wherein the forming of the layer of solder is performed by a process which includes one of electroplating and solder paste printing.

13. The method of claim 12, wherein the electroplated layer of solder is reflowed.

14. The method of claim 11, further comprising forming a layer of one of nickel and nickel-alloy on the top surface of the copper post prior to forming the layer of solder.

15. The method of claim 14, wherein the forming of the layer of nickel is performed by a process which includes one of electroplating and electroless plating.

16. The method of claim 9, wherein processing the dry film comprises
applying a mask on the dry film;
exposing the dry film to radiation; and
developing the dry film so as to expose the contact area.

17. The method of claim 16, wherein the radiation includes ultra-violet radiation or optical radiation.

18. The method of claim 9, wherein the dry film is developed with a solution of calcium carbonate.

19. The method of claim 9, wherein the dry film is removed with a solution of sodium hydroxide.

20. The method of claim 9, wherein the seed layer is etched away after removing the dry film.

21. A semiconductor device including:
a semiconductor chip comprising
at least one contact area for electrically connecting the chip to a substrate;
the contact area comprising a metallic contact pad covered by a seed layer; and
at least one copper interconnect post having a base surface directly contacting the contact area and extending from the contact area in a direction at least substantially perpendicular thereto in a tapered manner.
